(19) United States
(12) Patent Application Publication
(10) Pub. No.: US 2025/0248111 A1
(43) Pub. Date: Jul. 31, 2025

(54) Integration of Field Effect Transistors and Schottky Diodes on a Substrate

(71) Applicant: SCHOTTKY LSI, INC., Los Altos Hill, CA (US)

(72) Inventor: PIERRE DERMY, Los Altos Hills, CA (US)

(21) Appl. No.: 19/084,621

(22) Filed: Mar. 19, 2025

Related U.S. Application Data
(63) Continuation of application No. PCT/US2023/033153, filed on Sep. 19, 2023.
(60) Provisional application No. 63/408,796, filed on Sep. 21, 2022.
(60) Provisional application No. 63/494,365, filed on Apr. 5, 2023.
(60) Provisional application No. 63/509,250, filed on Jun. 20, 2023.

(51) Int. Cl. H10D 84/80; H10D 1/47; H10D 8/60; H10D 30/01; H10D 62/10; H10D 62/60; H10D 84/01

(52) U.S. Cl. CPC H10D 84/811; H10D 1/474; H10D 8/60; H10D 30/027; H10D 62/103; H10D 62/124; H10D 62/60; H10D 84/0109

(57) ABSTRACT

This application is directed to integrating field-effect transistors (FETs) and Schottky barrier diodes (SBDs) on a substrate and forming an integrated and planar semiconductor device. A P-type Metal Oxide Semiconductor (PMOS) transistor and a P-type SBD are formed on the substrate. The P-type SBD is formed by joining a P-type semiconductor and a first barrier metal. A doping concentration of the P-type channel of the PMOS transistor is established concurrently while a first portion of the P-type semiconductor of the SBD is formed. An extended drain structure of the PMOS transistor and a second portion of the P-type semiconductor are concurrently formed on the substrate concurrently. Distinct silicide contact surfaces for the extended drain structure of the PMOS transistor and the first portion and the second portion of the P-type semiconductor of the P-type SBD are formed concurrently.

### TECHNICAL FIELD

This application is a continuation of and claims benefits to International Patent Application No. PCT/US2023/033153, filed Sep. 19, 2023, titled “Integration of Field Effect Transistors and Schottky Diodes on a Substrate,” which claims priority to U.S. Provisional Application No. 63/408,796, filed Sep. 21, 2022, titled “Integration of Field Effect Transistors and Schottky Diodes on a Substrate,” U.S. Provisional Application No. 63/494,362, filed Apr. 5, 2023, titled “Front-End-Of-Line (FEOL) and Middle-of-Line (MOL) of Planar SCMOS Fabrication Processes,” and U.S. Provisional Application No. 63/509,250, filed Jun. 20, 2023, titled “Front-End-Of-Line (FEOL) and Middle-of-Line (MOL) of Planar SCMOS Fabrication Processes.” Each of these applications is incorporated by reference in its entirety.

### TECHNICAL FIELD

This application relates generally to integrated circuit (IC) devices, and more particularly to devices and methods for integrating field effect transistors (FETs) and Schottky barrier diodes (SBDs) on a semiconductor substrate.

### BACKGROUND

Various sectors of high technology industries have been driven by a sustained increase in device density of integrated circuits (IC's) during the past few decades. These high technology industries include semiconductor, electronics, computer, communication as well as their associated software fields for establishing system platforms and software applications. This increase in device density of the ICs has been made possible primarily by new photolithography techniques using shorter light wavelengths and/or by chemical and physical manufacturing processes having a desirable production yield, reproducibility, and quality control.

IC development has experienced multiple technology nodes corresponding to different semiconductor manufacturing process, design rules, circuit generations, and/or system architectures. Each technology node is achieved by reducing sizes of the ICs, improving performance of metal-oxide-semiconductor field-effect transistor (MOSFET), and increasing levels and densities of metal interconnections. Each new technology node is thereby more complex than a previous technology node, requiring more expensive microfabrication techniques, facilities and resources. Tools, time and manpower applied to implement very large scale integrated (VLSI) circuits also become more complex and costly at each new technology node. Prior to a 20 nm technology node, MOSFETs are integrated on a substrate with planar structures, and beyond the 20 nm technology node, MOSFETs start to adopt three-dimensional (3D) structures, adding a height to its channel width and allowing a shorter channel length. However, deployment of technology nodes have been focused on MOSFETs involving little or no other active semiconductor devices (e.g., a diode). It would be beneficial to engage different type of semiconductor devices into the integrated circuit than the current practice.

### SUMMARY

This application is directed to integrating planar field-effect transistors (FET) and Schottky barrier diodes (SBDs) on a substrate in a monolithic manner (e.g., via a planar semiconductor microfabrication process). Specifically, this application describes an overall IC manufacturing method of P-type and N-type SBDs. These SBDs are used with P-type and N-type MOSFETs that are offered in an existing or upcoming planar complementary metal-oxide-semiconductor (CMOS) technology node of large scale industrial production, thereby implementing Schottky-based complementary metal-oxide-semiconductor (SCMOS) ICs. Each portion of an SBD is formed from existing semiconductor manufacturing operations of the semiconductor microfabrication process without adding any masks, and therefore, corresponds to a respective portion of a FET. In some implementations, a feature size of at least one mask (e.g., a silicide defining mask) is reduced to facilitate concurrent formation of the SBDs with the FETs in the planar semiconductor microfabrication process.

In one aspect of the application, a method is implemented to form an integrated and planar semiconductor device. The method includes forming a P-type Metal Oxide Semiconductor (PMOS) transistor and a P-type SBD on a substrate. The P-type SBD is formed by joining a P-type semiconductor and a first barrier metal (e.g., a cathode). The method further includes establishing a doping concentration of the P-type channel of the PMOS transistor and forming a first portion of the P-type semiconductor of the P-type SBD concurrently, forming an extended drain structure of the PMOS transistor and a second portion of the P-type semiconductor on the substrate concurrently, and forming distinct silicide contact surfaces for the extended drain structure of the PMOS transistor and the first portion and the second portion of the P-type semiconductor of the P-type SBD concurrently.

In another aspect, an integrated planar semiconductor device includes a substrate, a PMOS transistor formed on the substrate, and a P-type SBD formed on a substrate and by joining a P-type semiconductor and a first barrier metal. A first doping concentration of the P-type channel of the PMOS transistor is substantially the same as that of a first portion of the P-type semiconductor of the SBD. A doping profile of an extended drain structure of the PMOS transistor is substantially the same as that of a second portion of the P-type semiconductor. Each of the extended drain structure of the PMOS transistor and the first portion and the second portion of the P-type semiconductor has a distinct silicide contact surface.

In yet another aspect of the invention, a method is implemented to form an integrated and planar semiconductor device. The method includes forming a N-type Metal Oxide Semiconductor (NMOS) transistor and an N-type SBD on a substrate. The N-type SBD is formed by joining an N-type semiconductor and a first barrier metal. The method further includes establishing a doping concentration of the N-type channel of the NMOS transistor and forming a first portion of the N-type semiconductor of the SBD concurrently, forming an extended drain structure of the NMOS transistor and a second portion of the N-type semiconductor concurrently on the substrate concurrently, and forming distinct silicide contact surfaces for the extended drain structure of the NMOS transistor and the first portion and the second portion of the N-type semiconductor of the N-type SBD concurrently.

In yet another aspect, an integrated planar semiconductor device includes a substrate, an N-type Metal Oxide Semiconductor (NMOS) transistor formed on the substrate, and an N-type SBD formed on a substrate and by joining an N-type semiconductor and a first barrier metal. A first doping concentration of the N-type channel of the NMOS transistor is substantially the same as that of a first portion of the N-type semiconductor of the SBD. A doping profile of an extended drain structure of the NMOS transistor is substantially the same as that of a second portion of the N-type semiconductor. Each of the extended drain structure of the NMOS transistor and the first portion and the second portion of the N-type semiconductor has a distinct silicide contact surface.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Description of Embodiments below, in conjunction with the following drawings in which like reference numerals refer to corresponding parts throughout the figures.

FIG. 1A is a schematic diagram of a three-input Schottky CMOS NAND logic gate integrating CMOS transistors and Schottky barrier diodes, in accordance with some implementations.

FIG. 1B is an IC layout diagram of a three-input NAND logic gate shown in FIG. 1A, in accordance with some implementations.

FIGS. 2A and 2B are two distinct cross-sectional views of an example integrated semiconductor device including a PMOS transistor and an N-type SBD, in accordance with some implementations.

FIGS. 2C and 2D are two distinct cross-sectional views of an example integrated semiconductor device including an NMOS transistor and a P-type SBD, in accordance with some implementations.

FIGS. 3A-3F are cross sectional views of an integrated semiconductor device that is processed in a front-end-of-the-line (FEOL) of a planar SCMOS fabrication process, in accordance with some implementations.

FIGS. 4A and 4B are two distinct cross-sectional views of another example integrated semiconductor device including an NMOS transistor and an N-type SBD, in accordance with some implementations.

FIGS. 4C and 4D are two distinct cross-sectional views of another example integrated semiconductor device including a PMOS transistor and a P-type SBD, in accordance with some implementations.

FIGS. 5A-5F are cross sectional views of another example integrated semiconductor device that is processed in a FEOL of a planar SCMOS fabrication process, in accordance with some implementations.

FIGS. 6A and 6B are two distinct cross-sectional views of an integrated semiconductor device that includes CMOS transistors and complementary SBDs and is processed up to completion of a FEOL of a planar SCMOS fabrication process, in accordance with some implementations.

FIGS. 7A and 7B are two distinct cross-sectional views of an integrated semiconductor device that includes CMOS transistors and complementary SBDs and is processed to a first metallic layer in a back-end-of-line (BEOL) of a planar SCMOS fabrication process, in accordance with some implementations.

Like reference numerals refer to corresponding parts throughout the several views of the drawings.

### DESCRIPTION OF EMBODIMENTS

This application is directed to a Schottky-based complementary metal oxide semiconductor (SCMOS) technology that integrates P-type and N-type Schottky barrier diodes (SBDs) in a planar CMOS microfabrication process. Each SBD is made by joining a barrier metal and a semiconductor structure. The barrier metal (e.g., Ni/CoEr) is doped with dopants and formed on a silicided diffusion tub (e.g., formed with sources and drains of CMOS transistors). Specifically, examples of the barrier metal include, but are not limited to, Nickel Silicide (NiSi) or Cobalt Silicide (CoSi₂). Other materials is optionally applied as the barrier metal when a surface is shallowly doped with impurity atoms of metal materials or coated with a thin layer of metal material (e.g., Nickel, Nickel Silicide, Cobalt, Cobalt Silicide, and the like). The silicided diffusion tub is formed concurrently with sources and drains of CMOS transistors. In some implementations, a photomask is adjusted to block or insert certain ions implanted in the silicided diffusion tubs of the SBDs. In an example, tub serial resistance is reduced to increase a diode current density.

Each SBD has electrical conduction characteristics that are determined by material compositions of the barrier metal and silicided diffusion tub, and more specifically, by impurity and physical properties of a metal-to-silicon interface at a diode junction of the SBD. Example electronic properties of this metal-to-silicon interface include, but are not limited to, a barrier height, which is associated with a turn-on/turn-off voltage of the SBD. In some implementations, a combination of the barrier metal and silicided diffusion tub results in relatively low values of the barrier height and the turn-on/off voltage of the Schottky barrier diode, compared to a threshold voltage of the MOSFETs integrated in the SCMOS technology. Thus, the Schottky barrier diode having a lower turn-on/off voltage is also called a low-threshold Schottky barrier diodes (LtSBDs).

In various implementations of this application, integration of the SBDs in a planar CMOS fabrication process (e.g., a in 28 nm or 65 nm technology node) is enabled by modifying a self-aligned silicidation module. A corresponding silicide defining photomask is involved in defining the SBDs. This photomask has a first critical dimension defining a feature size of the SBDs. In contrast, when it is used in a planar CMOS fabrication process involving no SBD, the silicide defining photomask has a second critical dimension (e.g., defining a feature size of a silicide resistor). The second critical dimension is greater than the first critical dimension associated with the SBDs. Although the silicide defining photomask is non-critical in the planar CMOS fabrication process, it becomes critical in the planar SCMOS fabrication process integrating the SBDs. A computer aided design (CAD) software tool is used to control a photomask making machine to print features of a circuit and device layout onto the silicide defining photomask according to logical formulas. Parameters applied in the logical formulas are modified to reflect a change of the critical dimension of the silicide defining photomask.

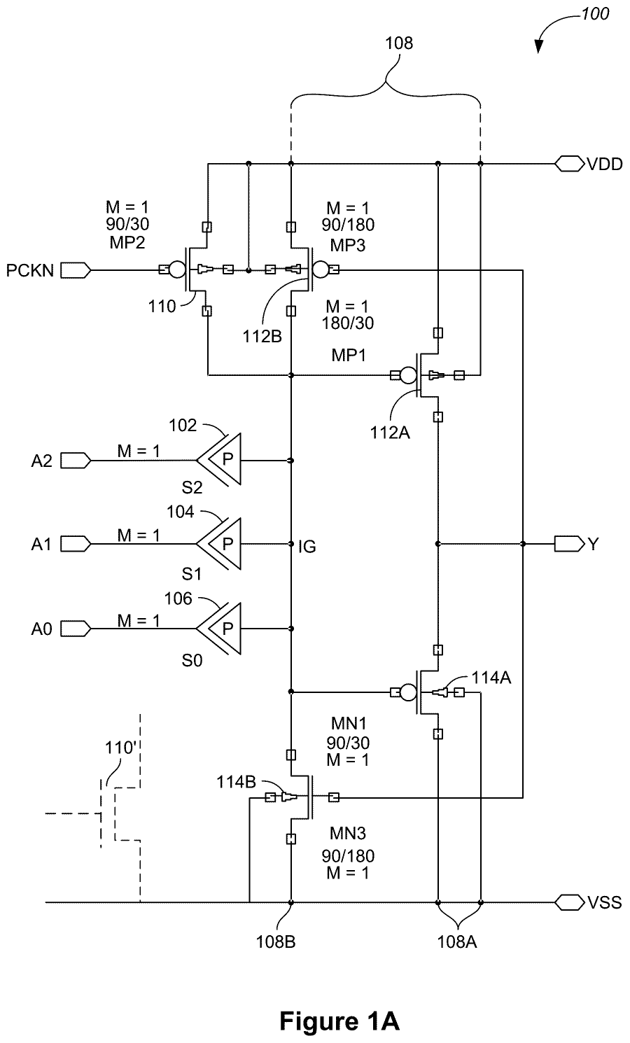

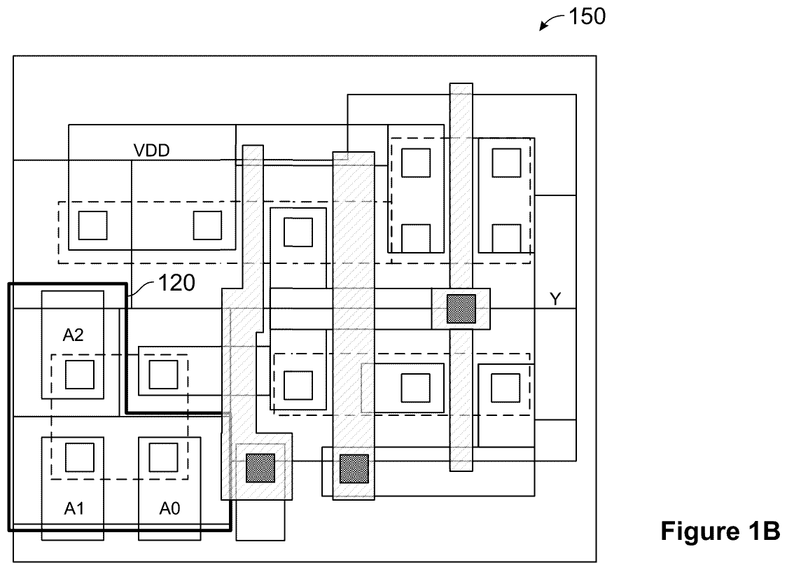

FIG. 1A is a schematic diagram of a three-input Schottky-CMOS NAND logic gate 100 integrating CMOS transistors and SBDs, in accordance with some implementations, and FIG. 1B is an IC layout diagram 150 of a three-input NAND logic gate shown in FIG. 1A, in accordance with some implementations. The three-input Schottky-CMOS NAND logic gate 100 includes three P-type SBDs 102, 104, and 106, a cross-coupled latch 108, and a control transistor 110. The cross-coupled latch 108 includes two CMOS inverters 108A and 108B, and an input and an output of the CMOS inverter 08A are cross-coupled to an output and an input of the CMOS inverter 108B, respectively. The CMOS inverter 108A includes a PMOS transistor 112A and an NMOS transistor 114A coupled in series with the PMOS transistor 112A. The CMOS inverter 108B includes a PMOS transistor 112B and an NMOS transistor 114B coupled in series with the PMOS transistor 112B. Input AO is coupled to a cathode of p-type SBD 102. Input Al is coupled to a cathode of p-type SBD 104. Input A2 is coupled to a cathode of p-type SBD 106. An anode of the SBD 102, an anode of the SBD 104, and an anode of the SBD 106 are coupled to each other. The anodes of the SBDs 102-106 are also coupled to the input of the CMOS inverter 108A (i.e., the gates of the PMOS transistor 112A and NMOS transistor 114A) and the output of the CMOS inverter 108B (i.e., the drains of the PMOS transistor 112B and NMOS transistor 114B). Conversely, an output Y of the NAND logic gate 100 is coupled to the output of the CMOS inverter 108A (i.e., the drains of the PMOS transistor 112A and NMOS transistor 114A) and the input of the CMOS inverter 108B (i.e., the gates of the PMOS transistor 112B and NMOS transistor 114B).

The CMOS inverters 108A and 108B are coupled between a high supply voltage VDD (e.g., 1.8V, 0.9V) and a low supply voltage VSS (e.g., ground, −1.8V). A source of the pull-up transistor 112A is coupled to the high supply voltage VDD, and a drain of the pull-up transistor 112B is coupled to the input of the CMOS inverter 108A and the anodes of the P-type SBDs 102-106. The control transistor 110 is controlled by an input signal PCKN. While the input signal PCKN is at the low supply voltage VSS, the input of the CMOS inverter 108A is at the high supply voltage VDD, and the output of the NAND logic gate 100 is the low supply voltage VSS. Conversely, while the input signal PCKN is at the high supply voltage VSS, the input of the CMOS inverter 108A is determined by a combination of the inputs A0, A1, and A2, so is the output of the NAND logic gate 100. As such, the NAND logic gate 100 is a dynamic logic controlled to be refreshed at a positive duty cycle of the input signal PCKN.

Referring to FIG. 1A, a Schottky-based CMOS implementation of the three-input NAND logic gate 100 uses the P-type control transistor 110 coupled to the anodes of the three SBDs 102-106. Conversely, in some implementations not shown, another Schottky-CMOS implementation of the three-input NAND logic gate uses an n-type transistor 100′ coupled to the anodes of the three SBDs 102-106 (replacing the PMOS control transistor 110). The N-type control transistor 110′ is coupled between the anodes of the three SBDs 102-106 and the low supply voltage VSS. In some implementations not shown, the three SBDs 102-106 are implemented by N-type SBDs that share an anode coupled to a control transistor 110 or 110′.

In some implementations not shown, the NAND logic gate 100 has a number of inputs (e.g., 2 inputs, 8 inputs), where the number is distinct from 3. Each input Aᵢ of the NAND logic gate 100 is coupled to a cathode of a respective P-type SBD, and the anode of the respective P-type SBD is coupled to the input of the CMOS inverter 108A. Each P-type SBD can be implemented by a PMOS or NMOS transistor in a counterpart planar CMOS fabrication process integrating no SBDs. As the number of the inputs and P-type SBDs increases, efficiency enhancement attained by replacing transistors with SBDs increases. Referring to FIG. 1B, the inputs A0, A1, and A2 are disposed on a region where the P-type SBDs 102-106 are formed. Compared with transistors formed in the counterpart planar CMOS fabrication process integrating no SBDs, the P-type SBDs 102-106 do not include any gate, channel, source, or drain structures and require a much smaller chip area.

In some implementations, the P-type SBDs 102-106 are formed in an N-well. In some implementations, at least one of the P-type SBDs 102-106 is formed jointly with a subset of the PMOS transistors 110, 112A, and 112B in an N-well. Further, in some embodiment, an anode of the at least one of the P-type SBDs 102-106 overlaps with a drain of the subset of the PMOS transistors 110, 112A, and 112B. Additionally, in some implementations, one or both of the NMOS transistors 114A and 114B are formed in a P-well that is optionally isolated from the N-well by field oxide or a trench.

As feature sizes of integrated circuit (IC) on silicon (Si) go down, more complex and diverse electronic functions are integrated on a single silicon die. CMOS IC is currently used as primary semiconductor technology to form very large scale integration (VLSI) logic and static random access memory (SRAM) IC's. An increase in density and complexity of VLSI is mainly due to sustained gradual reduction of a minimum feature size of both semiconductor functional circuit and corresponding metal interconnects. Specifically, a sustained increase in IC density and component count results from development of wafer processing plant equipment, tools and methods, which enables improvements of existing microfabrication techniques and transistor structures and application of new microfabrication techniques and transistor structures. The IC density and component count continue to increase as VLSI technology nodes changed from a planar CMOS fabrication process to a vertical fin-based CMOS fabrication process, e.g., in 2000-2010.

The vertical fin-based CMOS fabrication process is widely applied in the 16-22 nm technology node in which CMOS transistors have been built on fins with increased integration density and complexity. The vertical fin-based CMOS fabrication process is enabled by improvements in established, as well as new types of, semiconductor microfabrication equipment and procedures. For example, self-aligned multiple patterning is applied to increase an effective resolution of photolithography, and atomic layer deposition (ALD) is developed to control the layer deposition of various materials with thicknesses on a nanometer level. Plasma implantation is used to introduce semiconductor doping impurities. In some implementations, two sets of improvements are desirable in technology nodes. First, one desirable improvement of a technology node includes simultaneous increases of an operating speed and a reduction of IC die area and power dissipation. Second, another desirable improvement of a technology node includes using Schottky CMOS technology for both of the planar and vertical fin-based CMOS fabrication processes.

In some implementations, at least a half of transistors that are applied to implement a logic circuit block are replaced with LtSBDs. Each LtSBD has a diode area that is optionally smaller than half of a size of the smallest MOSFET, and therefore, the logic circuit block that integrates the LtSBDs have a smaller block area on a substrate. Additionally, the SBD-based logic circuit block (e.g., using SBDs) have less signal nets or interconnection wires than the transistor-based logic circuit block (e.g., using transistors without any SBDs). For example, the three-input NAND logic gate 100 has a device area of 0.84 μm×0.73 μm. When implemented entirely based on transistors, an area of a three-input NAND logic gate is greater than the device area of 0.84 μm×0.73 μm.

Benefits of SCMOS technology are extended to digital circuit, SRAM and non-volatile memory, and analog circuit. SCMOS offers a low-cost solution to keep up with the progress predicted by Moore's Law. SCMOS technology does not rely on size reduction of patterns printed on a semiconductor substrate or improvement of microfabrication steps and equipment. SCMOS technology does not require upgrade or addition of microfabrication equipment, nor does SCMOS technology require implementation of new and more complex silicon wafer processing steps. SCMOS reduces operational expenses of IC manufacturing. In any existing technology node, addition of LtSBDs requires a less extensive impact on existing reliability and quality assurance programs than for creating new transistor structures in a new technology node. Further, SBD-based circuit employs a smaller number of MOSFET device than transistor-based circuit, thereby removing corresponding photomasks and photolithography steps in some situations. Therefore, the total IC manufacturing cost of an established technology node is reduced by integrating SBDs and modifying circuit using SBDs. Various implementations of this application are directed to integration of SBDs in a planar silicone technology node with little or no change to an existing planar CMOS fabrication process.

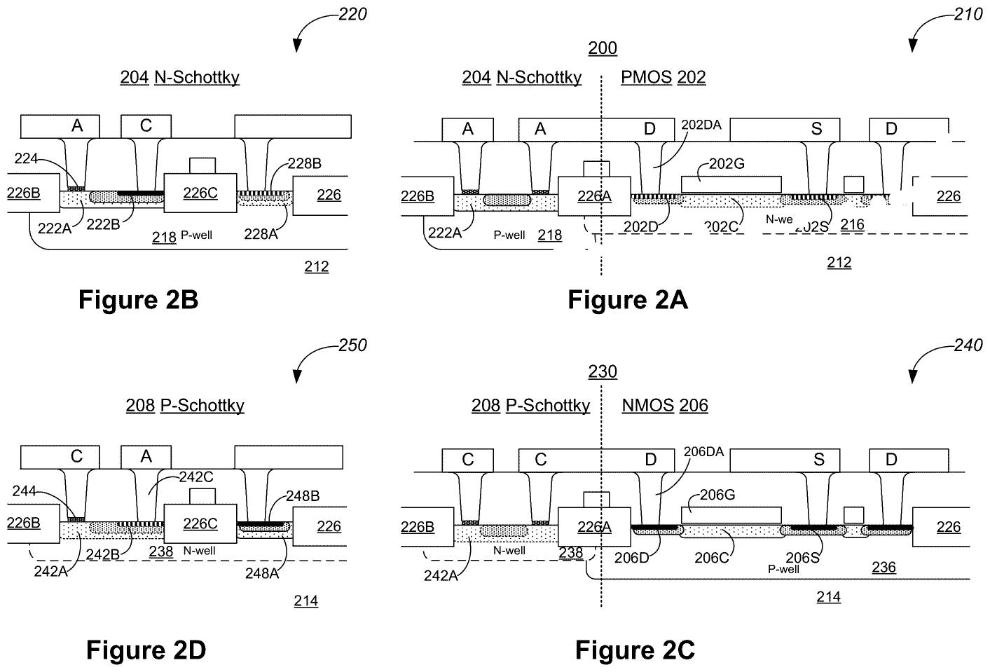

FIGS. 2A and 2B are two distinct cross-sectional views 210 and 220 of an integrated semiconductor device 200 including a PMOS transistor 202 and an N-type SBD 204, in accordance with some implementations. FIGS. 2C and 2D are two distinct cross-sectional views 240 and 250 of an integrated semiconductor device 230 including an NMOS transistor 206 and a P-type SBD 208, in accordance with some implementations. The cross-sectional views 210 and 220 correspond to two perpendicular lines on a top surface of a corresponding substrate, so are the cross-sectional views 240 and 250. The integrated semiconductor device 200 integrates the PMOS transistor 202 and N-type SBD 204 on a substrate 212, and the integrated semiconductor device 230 integrates the NMOS transistor 206 and P-type SBD 208 on a substrate 214.

In the integrated semiconductor device 200, the PMOS transistor 202 is formed in a first N-well 216, and the N-type SBD 204 is formed in a first P-well 218. The N-type SBD 204 joins an N-type semiconductor 222 and a barrier metal 224 (i.e., an anode). The first P-well 218 and N-well 216 are optionally connected to each other. A separation 226 is formed between the first P-well 218 and N-well 216 to enhance electrical isolation between the PMOS transistor 202 and N-type SBD 204. The separation 226A is located between the P-well 218 and N-well 216, and includes a field oxide region or a trench. In some implementations, each separation 226B is used at an edge of the N-well 216 or P-well 218. In some implementations, each separation 226C is used within a respective one of the N-well 216 and P-well 218 to separate two electrical structures (e.g., the N-type SBD 204 and a well contact 228). Conversely, in the integrated semiconductor device 230, the NMOS transistor 206 is formed in a second P-well 236, and the P-type SBD 208 is formed in a second N-well 238. The P-type SBD 208 joins a P-type semiconductor 242 and a barrier metal 244 (i.e., a cathode). The second P-well 236 is distinct from the first P-well 218, and the second N-well 238 is distinct from the second N-well 216. The second P-well 236 and N-well 238 are optionally connected to each other. A separation 226 is formed in a connecting region of the second P-well 236 and N-well 238 to enhance electrical isolation between the NMOS transistor 206 and P-type SBD 208.

The well contact 228 of the first P-well 218 is a combination of a first P-type portion 228A and a second P-type portion 228B, and the P-type portions 228A and 228B are formed with the first portion 242A and second portion 242B of the P-type semiconductor 242 of the P-type SBD 208, respectively. Stated another way, the P-type portions 228A and 228B are formed with the P-type channel 202C and extended drain structure of the PMOS transistor 202, respectively. The second portion 228B is formed in the first P-type portion 228A of the well contact 228 and has a distinct silicide contact surface. The well contact 248 of the second N-well 238 is a combination of a first N-type portion 248A and a second portion 248B, and the N-type portions 248A and 248B are formed with the first portion 222A and second portion 222B of the N-type semiconductor 222 of the N-type SBD 204, respectively. Stated another way, the N-type portions 248A and 248B are formed with the N-type channel 206C and extended drain structure 206D of the NMOS transistor 206, respectively. The second portion 248B is formed in the first N-type portion 248A of the well contact 248 and has a distinct silicide contact surface.

In some implementations, the substrates 212 and 214 are different portions of a silicon wafer processed by a common planar CMOS fabrication process, and separated from the silicon wafer after the planar CMOS fabrication process is completed. Optionally, the substrates 212 and 214 form a single substrate. Optionally, the substrates 212 and 214 are separate from each other. The PMOS transistor 202 has a P-type channel 202C and an extended drain structure 202D. The NMOS transistor 206 has an N-type channel 206C and an extended drain structure 206D. The N-type semiconductor 222 of the N-type SBD 204 has a first portion 222A forming an N-type diffusion tub and a second portion 222B sitting in the N-type diffusion tub of the first portion 222A. The P-type semiconductor 242 of the P-type SBD 208 has a first portion 242A forming a P-type diffusion tub and a second portion 242B sitting in the P-type diffusion tub of the first portion 242A.

The first portion 242A of the P-type semiconductor 242 of the P-type SBD 208 is formed jointly with and has the same doping concentration with the P-type channel 202C of the PMOS transistor 202. The second portion 242B of the P-type semiconductor 242 of the P-type SBD 208 is formed jointly with the extended drain structure 202D of the PMOS transistor 202. Distinct silicide contact surfaces for the extended drain structure 202D of the PMOS transistor 202 and the first portion 242A and the second portion 242B of the P-type semiconductor 242 of the P-type SBD 208 are formed concurrently. Additionally, the first portion 222A of the N-type semiconductor 222 of the N-type SBD 204 is formed jointly with and has the same doping concentration with the N-type channel 206C of the NMOS transistor 206. The second portion 222B of the N-type semiconductor 222 of the N-type SBD 204 is formed jointly with the extended drain structure 206D of the NMOS transistor 206. Distinct silicide contact surfaces for the extended drain structure 206D of the NMOS transistor 206 and the first portion 222A and the second portion 222B of the N-type semiconductor 222 of the N-type SBD 204 are formed concurrently. In some implementations, the distinct silicide contact surfaces for the extended drain structures of the PMOS transistor 202 and NMOS transistor 206, the first and second portions of the N-type semiconductor 222 of the N-type SBD 204, and the first and second portions of the P-type semiconductor 242 of the P-type SBD 208 are patterned and formed concurrently, e.g., using a single contact photomask (also called a salicide defining mask).

After the distinct silicide contact surfaces are opened using the single contact photomask, a layer of metallic material is deposited to fill contact holes formed on the distinct silicide contact surfaces of the PMOS transistor 202, NMOS transistor 206, P-type SBD 208, and/or N-type SBD 204. The layer of metallic material is patterned to provide a drain access 202DA coupled to the silicide contact surface of the extended drain structure 202D of the PMOS transistor 202, an anode access 242C coupled to the silicide contact surface of the second portion 242B of the P-type semiconductor 242 of the P-type SBD 208, the barrier metal 244 coupled to the silicide contact surface of the first portion 242A of the P-type semiconductor 242 of the P-type SBD 208. The layer of metallic material is also patterned to provide a drain access 206DA coupled to the silicide contact surface of the extended drain structure 206D of the NMOS transistor 206, A cathode access 222C coupled to the silicide contact surface of the second portion 222B of the N-type semiconductor 222 of the N-type SBD 204, the barrier metal 224 coupled to the silicide contact surface of the first portion 222A of the N-type semiconductor 222 of the N-type SBD 204.

Each and every functional portion of an SBD 204 or 208 corresponds to a counterpart portion in a transistor. Specifically, a first interconnect layer of the transistor corresponds to a metal layer of the SBD, and a transistor channel having threshold voltage enhancement doping corresponds to a semiconductor portion (e.g., 222A and 242A) of the SBD, while an extended drain structure of the transistor is reconfigured to provide an ohmic contact with the semiconductor portion of the SBD. Although the functional portions of the SBD 204 or 208 already exist in a CMOS fabrication process, a CMOS technology node (e.g., 0.350 μm or lower) is implemented based on at least a self-aligned silicidation (SAS) photomask, i.e., a salicide defining mask, and the SAS photomask is modified to integrate the SBD. In the CMOS fabrication process, the SAS photomask is used to define one or more resistors and has a critical dimension that defines a minimum feature size of the one or more resistors. This critical dimension is greater than critical dimensions of a set of other photomasks (e.g., those defining gate, metal contacts). The SAS photomask allows relaxed tolerances of feature widths and spaces to be printed on a semiconductor substrate. In an example, the critical dimension of the SAS photomask exceeds a critical line such that the SAS photomask is labelled as non-critical. In various implementations of this application, this SAS photomask is changed to a critical mask having a small critical dimension (e.g., less than a predefined critical threshold) for the purposes of integrating the SBDs in the CMOS fabrication process.

Each CMOS technology node has a most critical photomask whose critical dimension is the smallest among all photomasks used in the technology node, and the most critical photomask is a gate photomask defining gates of CMOS transistors formed in the technology node. SCMOS technology integrates LtSBDs in the CMOS technology node and is applied in VLSI applications. The SCMOS technology builds P and N LtSBDs, and each LtSBD occupies a smaller area than a diode-connected counterpart transistor. Each LtSBD is formed on a device active area (i.e., a diffusion tub), and the device active area is formed directly on a respective well depending on a corresponding circuit function and electrical isolation requirements. Each LtSBD includes a barrier metal making contact with a lightly doped semiconductor surface having an impurity concentration of 10¹⁵-10¹⁸ atoms/cm³. The lightly doped semiconductor surface is doped with arsenic (As), phosphorus (P), or antimony (Sb), Boron (B), preferably according to a retrograde profile.

Examples of the barrier metals 224 and 244 include, but are not limited to, Nickel Silicide (NiSi), Silicide (TiSi), or Cobalt Silicide (CoSi₂). Other materials is optionally applied as the barrier metal when a surface is shallowly doped with impurity atoms of metal materials or coated with a thin layer of metal material (e.g., Nickel, Nickel Silicide, Cobalt, Cobalt Silicide, and the like). Specifically, a barrier metal (e.g., Co, Ti) is combined with well doping and transistor threshold adjustment implantations, thereby forming the Nickel Silicide (NiSi), Silicide (TiSi), or Cobalt Silicide (CoSi2). The LtSBDs can be built with the necessary electrical characteristics to operate with a set of MOSFETs in an SCMOS circuit application. Further, in some implementations, each P-type or N-type SBD has a respective Schottky barrier height voltage that is in a range of Schottky barrier height voltage. The respective Schottky barrier height voltage varies with a temperature of the respective SBD. In some implementations, an SBD is separated from an immediately adjacent SBD or transistor by a trench. Ion implantation is optionally applied to adjust a doping concentration of the diffusion tub or device active area of the SBD, thereby suppressing a reverse bias current of the SBD below a leakage current tolerance.

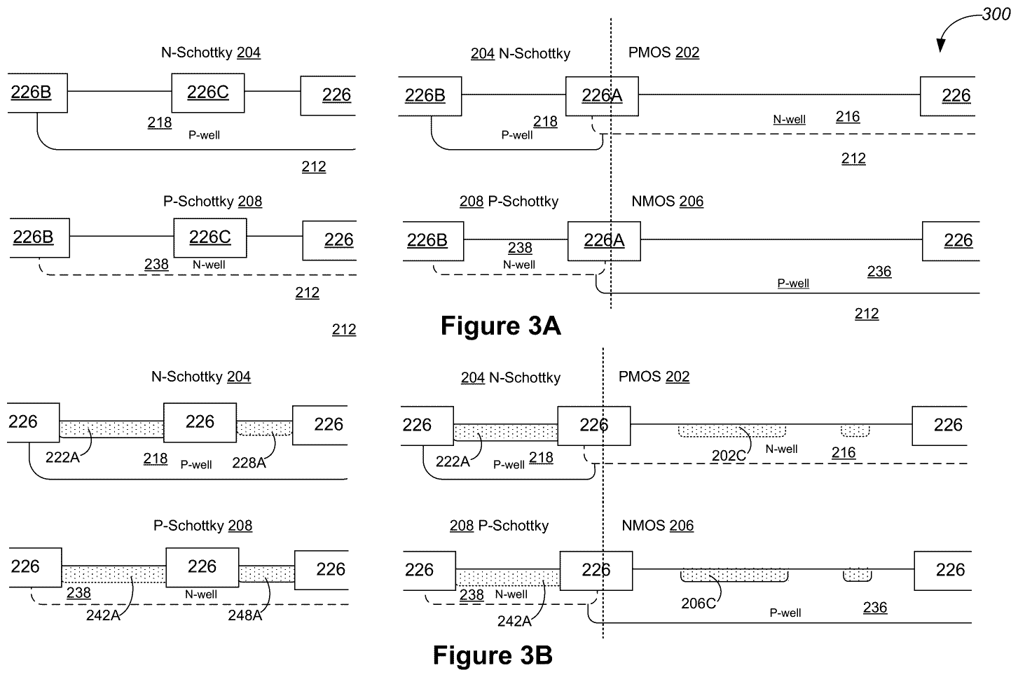

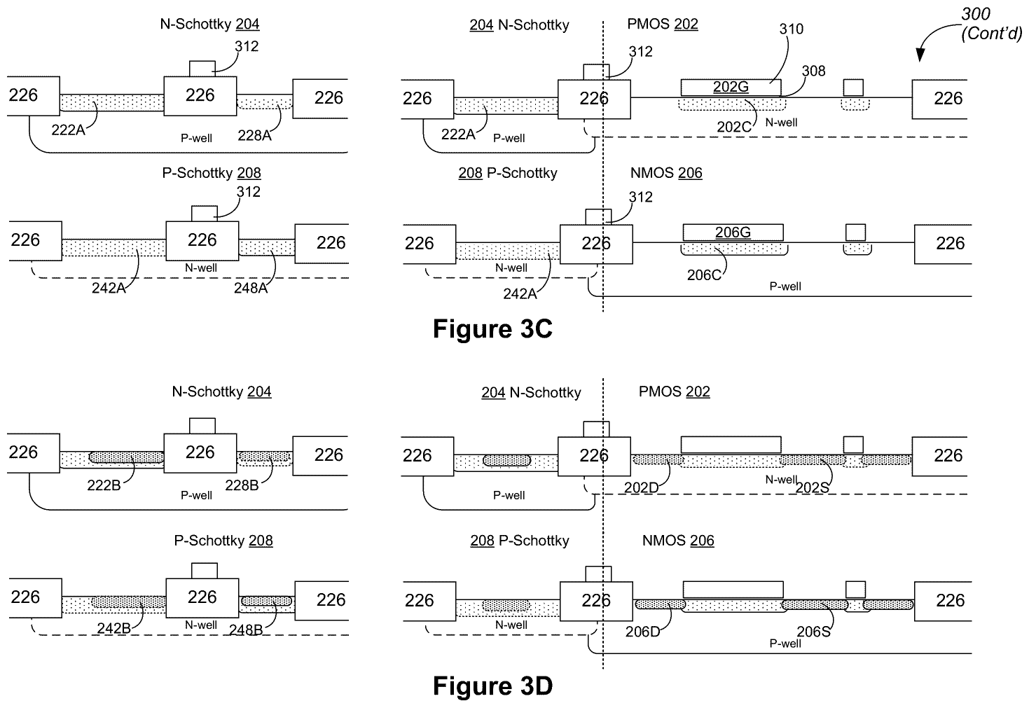

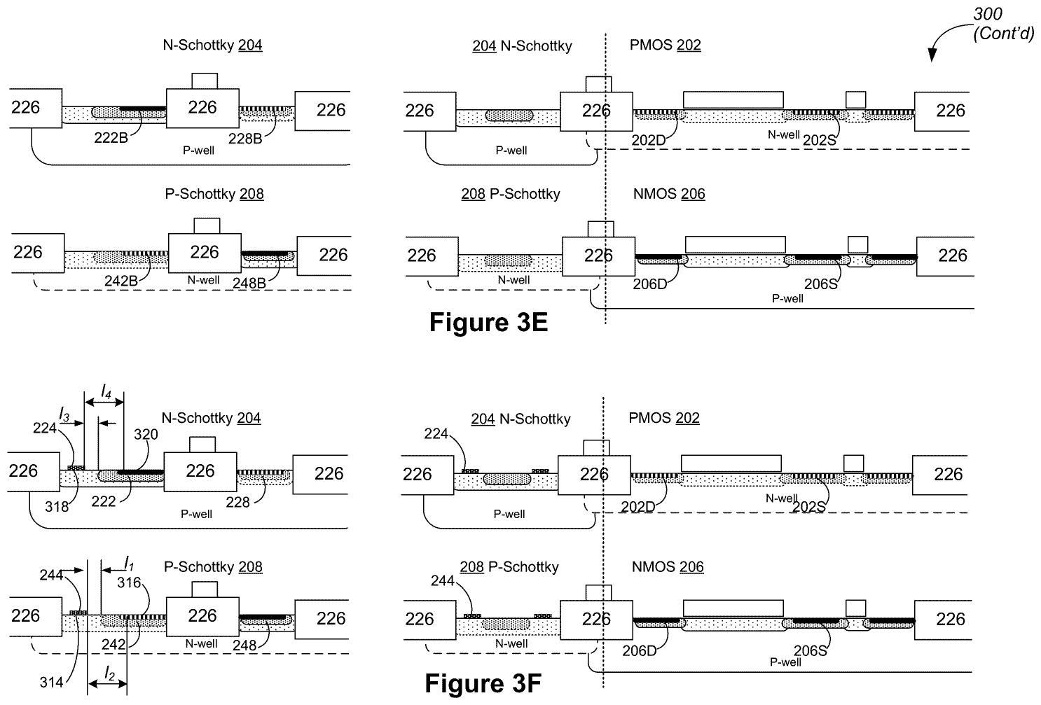

FIGS. 3A-3F are cross sectional views of an integrated semiconductor device 200 that is processed in a Front-End-of-the-Line (FEOL) of a planar SCMOS fabrication process 300, in accordance with some implementations. The integrated semiconductor device 200 includes at least one of a PMOS transistor 202, an NMOS transistor 206, a P-type SBD 208, and an N-type SBD 204, and is manufactured on a substrate 212 by the planar Schottky-based CMOS (SCMOS) fabrication process 300. Optionally, the substrate 212 includes a P-Type bulk silicon (e.g., having a resistivity of 10 ohm.cm). Optionally, the substrate 212 includes a silicon-on-insulator (SOI). Optionally, the substrate 212 has an epitaxial silicon layer formed on a buried oxide. The SCMOS fabrication process 300 corresponds to a technology node (e.g., a 0.250 μm, 0.180 μm, 22 nm, or 20 nm technology node). The integrated semiconductor device 200 includes a VLSI logic, memory, digital circuit, analog circuit, or a combination thereof. Additionally, the SCMOS fabrication process 300 includes silicidation of source regions, drain regions, and gates of both the PMOS device 202 and the NMOS device 206. In some implementations, silicidation occurs to contiguous wire segments coupled to the different portions of the PMOS and NMOS devices 202 and 206. Silicidation defines a plurality of silicided areas and is enabled by an SAS photomask and associated photolithography, patterning, or material removal steps. Such a processing module is referred to as self-aligned silicidation (SAS) or salicidation. The SAS photomask is also called a resistor protecting oxide (RPO) photomask or a self-aligned silicidation blocking (SASB) photomask.

Referring to FIG. 3A, the substrate 212 is implanted to form a first N-well 216, a first P-well 218, a second P-well 236, and a second N-well 238. In some implementations, two separate well photomasks are applied to define P-wells and N-wells that are implanted with different types of dopants of different doping concentrations, respectively. In some implementations, the substrate 212 is P-type, and at least one of the first and second P-wells 218 and 236 is formed within a corresponding N-well 216 or 238. Alternatively, in some implementations, the first P-well 218 is immediately adjacent to the first N-well 216, and the second N-well 238 is immediately adjacent to the second P-well 236. A plurality of separations 226 are formed in the P-wells 218 and 236 and N-wells 216 and 238, and each separation 226 includes a field oxide region or a trench. Optionally, a separation 226A is formed in a connecting region between a P-well and an N-well. Optionally, a separation 226B is used at an edge of the N-well 216 or 238 or P-well 218 or 236. Optionally, a separation 226C is used within one of the P-wells 218 and 236 and N-wells 216 and 238 to separate two electrical structures formed therein. As such, device active areas are defined by the P-wells 218 and 236, N-wells 216 and 238, and separations 226.

Referring to FIG. 3B, threshold adjustment ion implants are applied in the P-wells 218 and 236 and N-wells 216 and 238. Specifically, in response to a first threshold adjustment ion implant, a doping concentration of the P-type channel 202C of the PMOS transistor 202 is established in the first N-well 216, concurrently while a first portion 242A of the P-type semiconductor 242 of the P-type SBD 208. In some situation, the first P-well 218 or second P-well 236 has a well contact 228 that provides a low-resistance path for the P-well 218 or 236, and the well contact 228 has a first P-type portion 228A that is formed concurrently with the P-type channel 202C of the PMOS transistor 202 and the first portion 242A of the P-type semiconductor 242 of the P-type SBD 208. Further, in some implementations, in response to a second threshold adjustment ion implant, a doping concentration of the N-type channel 206C of the NMOS transistor 206 is established in the second P-well 236, concurrently while a first portion 222A of the N-type semiconductor 222 of the N-type SBD 204. In some situation, the first N-well 216 or second N-well 218 has a well contact 248 that is a low-resistance path, and the well contact 248 has a first N-type portion 248A that is formed concurrently with the N-type channel 206C of the NMOS transistor 206 and the first portion 222A of the N-type semiconductor 222 of the N-type SBD 204.

In some implementations, the PMOS transistor 202 is a first PMOS transistor. A second PMOS transistor is configured to operate with a second P-type channel. The second P-type channel has an alternative doping concentration distinct from the doping concentration of the P-type channel 202C of the first PMOS transistor 202, such that a first threshold voltage of the first PMOS transistor 202 is distinct from a second threshold voltage of the second PMOS transistor. The alternative doping concentration of the second P-type channel of the second PMOS transistor is established separately from the P-type channel 202C of the first PMOS transistor 202 and the first portion 242A of the P-type semiconductor 242 of the P-type SBD 208.

In some implementations, the NMOS transistor 206 is a first NMOS transistor. A second NMOS transistor is configured to operate with a second N-type channel. The second N-type channel has an alternative doping concentration distinct from the doping concentration of the N-type channel 206C of the first NMOS transistor 206, such that a third threshold voltage of the first NMOS transistor 206 is distinct from a fourth threshold voltage of the second NMOS transistor. The alternative doping concentration of the second N-type channel of the second NMOS transistor is established separately from the N-type channel 206C of the first NMOS transistor 206 and the first portion 222A of the N-type semiconductor 222 of the N-type SBD 204.

Referring to FIG. 3C, surface of the substrate 212 is cleaned, and a gate oxide layer 308 is formed on the substrate 212 for the P-type and N-type transistors 202 and 206. In some implementations, more than one gate oxide layers 308 are applied to define gate oxide having different thicknesses for different transistors. For example, the integrated semiconductor device 300 has two different gate oxide thicknesses, and each transistor 202 or 206 has a respective one of the two gate oxide thicknesses. Transistors of core circuit have a first gate oxide thickness, and transistors of input/output circuit have a second gate oxide thickness that is greater than the first gate oxide thickness. After the gate oxide layer 308 is formed, a layer of gate material (e.g. metal or polysilicon) 310 is deposited on the gate oxide layer 308, and is optionally patterned jointly with the gate oxide layer 308. The gate layer 310 is thereby patterned to a gate 202G of the PMOS transistor 202, a gate 206G of the NMOS transistor 206, and a plurality of separation gates 312 formed on top of the separation 226. In some implementations, a subset of the threshold adjustment ion implants in FIG. 3B is applied after the gate oxide layer 308 and gate layer 310 are deposited or patterned, i.e., the subset of the threshold adjustment ion implants penetrate the gate oxide layer and gate layer 310 to reach one or more of: the P-type channel 202C, the N-type channel 206C, the first portion 222A of the N-type semiconductor 222, and the first portion 242A of the P-type semiconductor 242.

Referring to FIG. 3D, a first lightly doped source and drain implant (P-type) is applied to form lightly doped regions of the source structure 202S and extended drain structure 202D of the PMOS transistor 202. A lightly doped region of the second portion 242B of the P-type semiconductor 242 of the P-type SBD 208 is formed via the same first lightly doped source and drain implant, so is a lightly doped region of the well contact 228 of the first P-well 218. A second lightly doped source and drain implant (N-type) is applied to form lightly doped regions of the source structure 206S and extended drain structures 206D of the NMOS transistor 206. A lightly doped region of the second portion 222B of the N-type semiconductor 222 of the N-type SBD 204 is formed via the same second lightly doped source and drain implant, so is a lightly doped region of the well contact 248 of the second N-well 238.

Referring to FIG. 3E, a first heavily doped source and drain implant (P-type) is applied to form heavily doped regions of the source structure 202S and extended drain structures 202D of the PMOS transistor 202. A heavily doped region of the second portion 242B of the P-type semiconductor 242 of the P-type SBD 208 is formed via the same first heavily doped source and drain implant, so is a heavily doped region of the well contact 228 of the first P-well 218. A second heavily doped source and drain implant (N-type) is applied to form heavily doped regions of the source structure 206S and extended drain structures 206D of the NMOS transistor 206. A heavily doped region of the second portion 222B of the N-type semiconductor 222 of the N-type SBD 204 is formed via the same second heavily doped source and drain implant, so is a heavily doped region of the well contact 248 of the second N-well 238. Each of these heavily doped regions sits within, and is integrated with, a respective lightly doped region of the same device structure.

Referring to FIG. 3F, a silicon nitride (Si₃N₄) hard mask (RPO/SASB) is used to block silicidation. Portions of surfaces of the gate, source and drain structures of the transistors 202 and 206 are exposed via the Si₃N₄ hard mask, so are portions of surfaces of the first and second portions of the SBDs 204 and 208. A barrier metal 224 or 244 (e.g., Pt, Ti or Co) is deposited on the Si₃N₄ hard mask and treated by heat to induce silicidation, while low-ohmic contacts are formed onto the exposed portions of surfaces of the gate, source and drain structures of the transistors 202 and 206 and the first and second portions of the SBDs 204 and 208. In some implementations, additional resistor areas are exposed via the Si₃N₄ hard mask, and salicidation occurs to the resistor areas to form resistors.

In some implementations, a silicide defining mask has a predefined critical dimension CD. In accordance with the silicide defining mask, a first silicide contact surface 314 is defined on the first portion 242A of the P-type semiconductor 242 of the P-type SBD 208, and a second silicide contact surface 316 is defined on the second portion 242B of the P-type semiconductor 242. The first silicide contact surface 314 is separated from the second portion 242B of the P-type semiconductor 242 of the P-type SBD 208 by a lateral distance l₁. The first silicide contact surface 314 is separated from the second silicide contact surface 316 by a lateral distance l₂. The lateral distances l₁ and l₂ are greater than the predefined critical dimension CD. In some implementations, in accordance with the silicide defining mask, a first silicide contact surface 318 is defined on the first portion 222A of the N-type semiconductor 222 of the N-type SBD 204, and a second silicide contact surface 320 is defined on the second portion 222B of the N-type semiconductor 222 of the N-type SBD 204. The first silicide contact surface 318 is separated from the second portion 222B of the N-type semiconductor 222 of the N-type SBD 204 by a lateral distance l₃. The first silicide contact surface 318 is separated from the second silicide contact surface 320 by a lateral distance l₄. The lateral distances l₃ and l₄ are greater than the predefined critical dimension CD. Further, in some implementations not shown, in accordance with the silicide defining mask, a silicide resistor is defined on the substrate 212. The silicide resistor is distinct from the extended drain structure 202D of the PMOS transistor 202 and the first portion 242A and the second portion 242B of the P-type semiconductor 242 of the P-type SBD 208. The lateral distances l₁-l₄ are controlled by the predefined critical dimension CD, and the silicide defining mask is a critical mask for the planar SCMOS fabrication process 300.

After the FEOL of the planar SCMOS fabrication process 300, a low-dielectric SiO₂-based dielectric layer is deposited and planarized, e.g., by chemical-mechanical polishing (CMP). Contacts are opened on the dielectric layer, and a metallic layer of interconnects are formed to access the gate, source and drain structures of the transistors 202 and 206 and the second portions and barrier metals of the SBDs 204 and 208 via the opened contacts. The metallic layer of interconnects are optionally made of aluminum (Al) or copper (Cu). In some implementations, a dual damascene process is applied, e.g., at a 0.18 μm or 0.13 μm level.

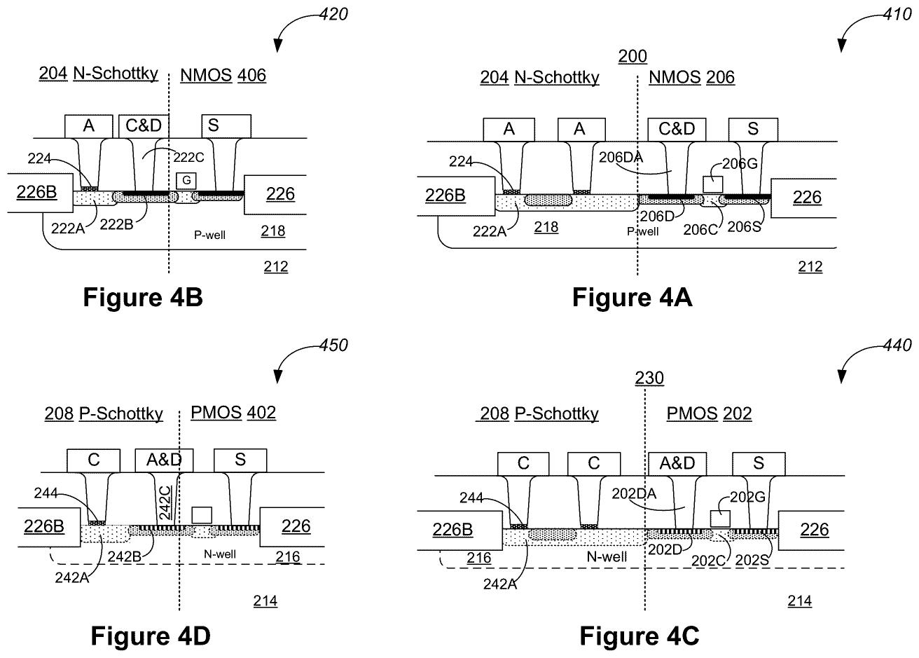

FIGS. 4A and 4B are two distinct cross-sectional views 410 and 420 of another example integrated semiconductor device 200 including an NMOS transistor 206 and an N-type SBD 204, in accordance with some implementations. FIGS. 4C and 4D are two distinct cross-sectional views 440 and 450 of another example integrated semiconductor device 230 including a PMOS transistor 202 and a P-type SBD 208, in accordance with some implementations. The cross-sectional views 410 and 420 correspond to two perpendicular lines on a top surface of a corresponding substrate 212, so are the cross-sectional views 440 and 450. The integrated semiconductor device 200 integrates the NMOS transistor 206 and N-type SBD 204 on the substrate 212, and the integrated semiconductor device 230 integrates the PMOS transistor 202 and P-type SBD 208 on a substrate 214.

Referring to FIGS. 4A and 4B, the integrated semiconductor device 200 is planar. The N-type SBD 204 is formed on the substrate 214 and by joining an N-type semiconductor 222 and a barrier metal 224 (i.e., an anode). A first doping concentration of the N-type channel 206C of the NMOS transistor 206 is substantially the same as that of a first portion 222A of the N-type semiconductor 222 of the N-type SBD 204. A doping profile of an extended drain structure 206D of the NMOS transistor 206 is substantially the same as that of a second portion 222B of the N-type semiconductor 222 of the N-type SBD 204. Each of the extended drain structure 206D of the NMOS transistor 206 and the first portion 222A and the second portion 222B of the N-type semiconductor 222 has a distinct silicide contact surface. During a planar SCMOS fabrication process, the first doping concentration of the N-type channel 206C of the NMOS transistor 206 is established concurrently with formation of the first portion 222A of the N-type semiconductor 222 of the N-type SBD 204, e.g., by way of one or more ion implantation operations. The extended drain structure 206D of the NMOS transistor 206 is formed concurrently with the second portion 222B of the N-type semiconductor 222 of the N-type SBD 204, e.g., using the same ion implantation or diffusion operation. Distinct silicide contact surfaces of the extended drain structure 206D of the NMOS transistor 206 and the first portion 222A and the second portion 222B of the N-type semiconductor 222 are patterned and formed concurrently. In this example, the NMOS transistor 206 and N-type SBD 204 are integrated in a first P-Well 218.

Referring to FIGS. 4C and 4D, the integrated semiconductor device 230 is planar. The P-type SBD 208 is formed on the substrate 214 and by joining a P-type semiconductor 242 and a barrier metal 244 (i.e., a cathode). A first doping concentration of the P-type channel 202C of the PMOS transistor 202 is substantially the same as that of a first portion 242A of the P-type semiconductor 242 of the P-type SBD 208. A doping profile of an extended drain structure 202D of the PMOS transistor 202 is substantially the same as that of a second portion 242B of the P-type semiconductor 242 of the P-type SBD 208. Each of the extended drain structure 202D of the PMOS transistor 202 and the first portion 242A and the second portion 242B of the P-type semiconductor 242 has a distinct silicide contact surface. During a planar SCMOS fabrication process, the doping concentration of the P-type channel 202C of the PMOS transistor 202 is established concurrently with formation of the first portion 242A of the P-type semiconductor 242 of the P-type SBD 208, e.g., by way of one or more ion implantation operations. The extended drain structure 202D of the PMOS transistor 202 is formed concurrently with the second portion 242B of the P-type semiconductor 242 of the P-type SBD 208, e.g., using the same ion implantation or diffusion operation. Distinct silicide contact surfaces of the extended drain structure 202D of the PMOS transistor 202 and the first portion 242A and the second portion 242B of the P-type semiconductor 242 are patterned and formed concurrently. In this example, the NMOS transistor 206 and N-type SBD 204 are integrated in a first N-Well 216.

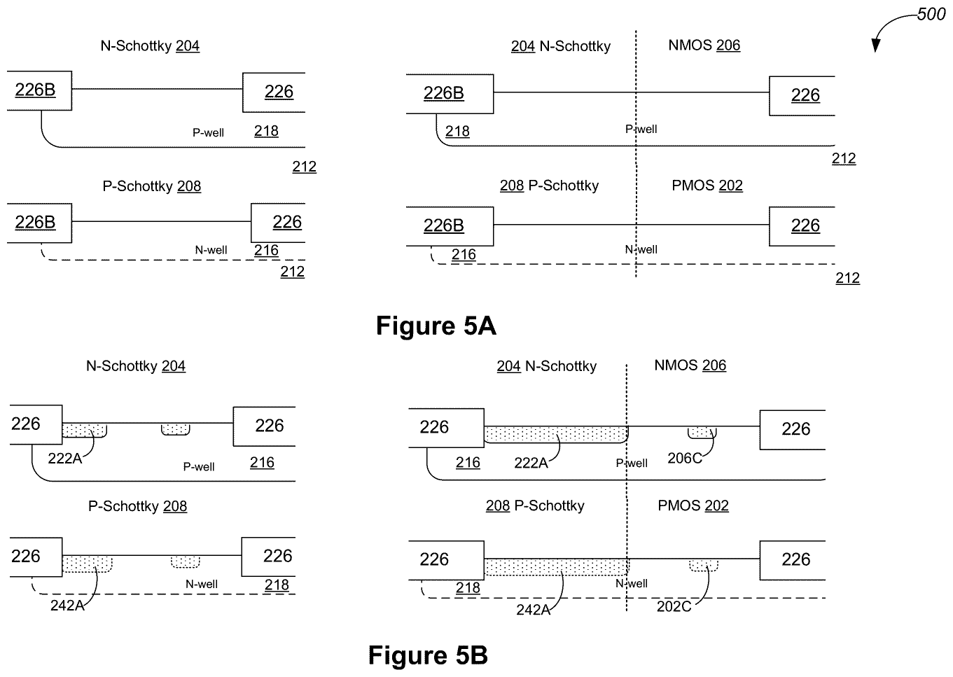

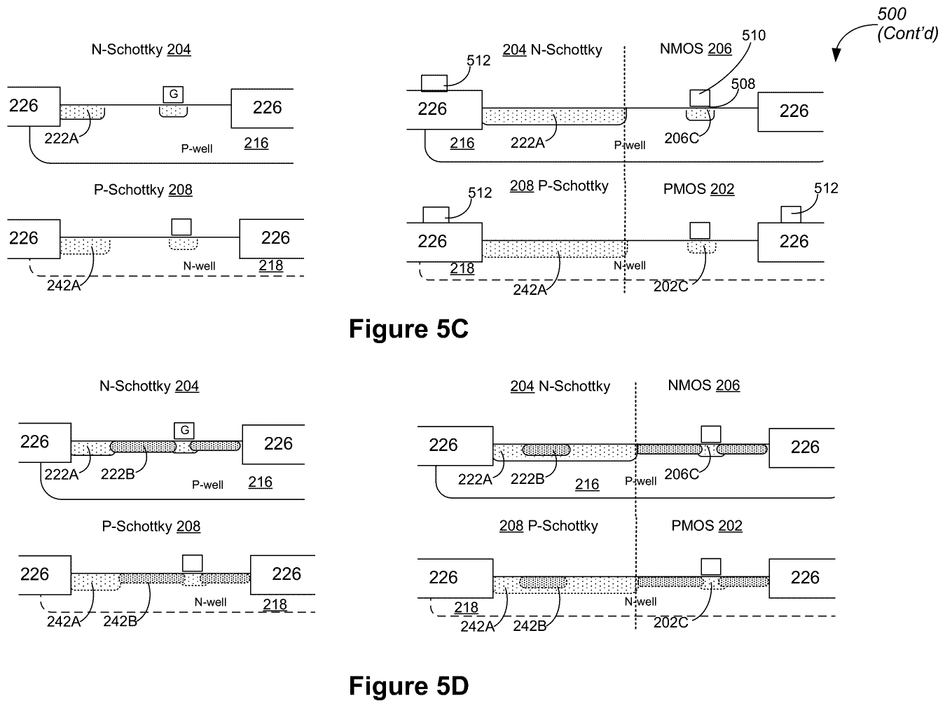

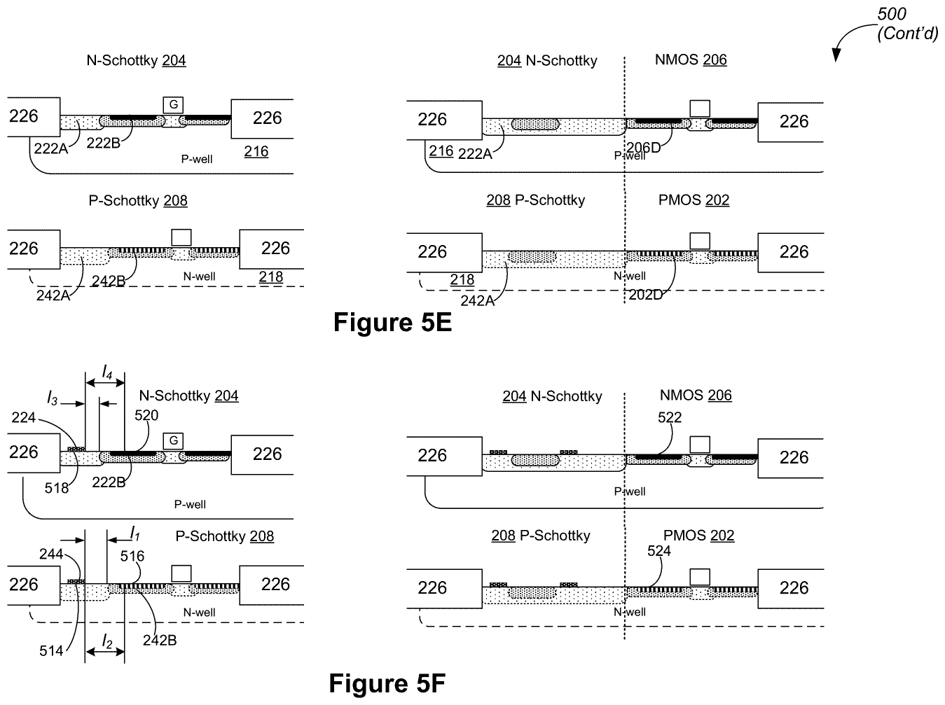

FIGS. 5A-5F are cross sectional views of another example integrated semiconductor device 200 that is processed in a FEOL of a planar Schottky CMOS fabrication process 500, in accordance with some implementations. The integrated semiconductor device 200 includes at least one of a PMOS transistor 202, an NMOS transistor 206, a P-type SBD 208, and an N-type SBD 204, and is manufactured on a substrate 212 by the planar Schottky CMOS (SCMOS) fabrication process 500. The SCMOS fabrication process 500 includes concurrent silicidation of contact surfaces of source regions, drain regions, and gates of both the NMOS and PMOS devices 206 and 202 and silicidation of contact surfaces of the semiconductors of the N-type and P-type SBDs 204 and 208. In some implementations, silicidation occurs to contiguous wire segments coupled to the different portions of the NMOS and PMOS devices 206 and 202. Silicidation defines a plurality of silicided areas and is enabled by an SAS photomask and associated photolithography, patterning, or material removal steps. Such a processing module is referred to as self-aligned silicidation (SAS) or salicidation.

Referring to FIG. 5A, the substrate 212 is implanted to form an N-well 216 and an P-well 218. In some implementations, two separate well photomasks are applied to define the P-well 218 and N-well 216 that are implanted with different types of dopants of different doping concentrations, respectively. In some implementations, the substrate 212 is P-type, and the P-well 218 is formed within the N-well 216. Alternatively, in some implementations, the P-well 218 is separate from the N-well 216. A plurality of separations 226 are formed between the P-well 218 and N-well 216, in the P-well 218, and/or in the N-well 216. Each separation 226 includes a field oxide region or a trench. Optionally, a separation 226 is formed in a connecting region between the P-well 218 and N-well 216. Optionally, a separation 226B is used at an edge of the N-well 216 or P-well 218. Optionally, a separation 226 is used within one of the N-well 216 or P-well 218 to separate two electrical structures formed therein. As such, device active areas are defined by way of the N-well 216, P-well 218, and separations 226.

Referring to FIG. 5B, threshold adjustment ion implants are applied in the P-well 218 and N-well 216. Specifically, in response to a first threshold adjustment ion implant, a doping concentration of the N-type channel 206C of the NMOS transistor 206 is established in the P-well 218, concurrently while a first portion 222A of the N-type semiconductor 222 of the N-type SBD 204 is formed. A second portion 222B is connected to the first portion 222A of the N-type semiconductor 222 of the N-type SBD 204, and formed concurrently with an extended drain structure 206D of the NMOS transistor 206. Optionally, the NMOS transistor 206 also has an extended source structure 206S that is formed concurrently with the extended drain structure 206D and second portion 222B. In some implementations, another NMOS device 406 is disposed immediately adjacent to the N-type SBD 204, and the second portion 222B is shared with the NMOS device 406, i.e., used as an extended source or drain structure of the NMOS device 406. In an example, the NMOS device 406 is the same device of the NMOS device 206.

In some implementations, the NMOS transistor 206 is a first NMOS transistor. The integrated semiconductor device 200 includes one or more second NMOS transistors each of which is configured to operate with a second N-type channel. The second N-type channel has an alternative doping concentration distinct from the doping concentration of the N-type channel of the first NMOS transistor 206, such that a third threshold voltage of the first NMOS transistor 206 is distinct from a fourth threshold voltage of the second NMOS transistors. The alternative doping concentration of the second N-type channel of the second NMOS transistors is established separately from the N-type channel 206C of the first NMOS transistor 206 and the first portion 222A of the N-type semiconductor 222 of the N-type SBD 204.

In response to a second threshold adjustment ion implant, a doping concentration of the P-type channel 202C of the PMOS transistor 202 is established in the N-well 216, concurrently while a first portion 242A of the P-type semiconductor 242 of the P-type SBD 208 is formed. A second portion 242B is connected to first portion 242A of the P-type semiconductor 242 of the P-type SBD 208, and formed concurrently with an extended drain structure 202D of the PMOS transistor 202. Optionally, the PMOS transistor 202 also has an extended source structure 202S that is formed concurrently with the extended drain structure 202D and second portion 242B.

In some implementations, a PMOS device 402 is disposed immediately adjacent to the P-type SBD 208, and the second portion 242B is shared with the PMOS device 402, i.e., used as an extended source or drain structure of the PMOS device 402. In an example, the PMOS device 402 is the same device of the PMOS device 202. Additionally, in some embodiments, the P-type SBD 208 is applied in the NAND logic gate 100 for receiving an input Aᵢ, and the PMOS device 402 corresponds to the PMOS transistor 110 or 112B. The second portion 242B of the P-type semiconductor 242 (i.e., the anode) of the P-type SBD 208 shares a physical structure with the extended source or drain structure of the PMOS transistor 110 or 112B.

In some implementations, the PMOS transistor 202 is a first PMOS transistor. The integrated semiconductor device 200 includes one or more second PMOS transistors each of which is configured to operate with a second P-type channel having an alternative doping concentration distinct from the doping concentration of the P-type channel 202C of the PMOS transistor 202. A threshold voltage of the PMOS transistor 202 is distinct from a threshold voltage of the one or more second PMOS transistors. The alternative doping concentration of the second P-type channel of the second PMOS transistors is established separately from the P-type channel 202C of the first PMOS transistor 202 and the first portion 242A of the P-type semiconductor 242 of the P-type SBD 208.

Referring to FIG. 5C, surface of the substrate 212 is cleaned, and a gate oxide layer 508 is formed on the substrate 212 for the P-type and N-type transistors. In some implementations, more than one gate oxide layers 508 are applied to define gate oxide having different thicknesses for different transistors. For example, the integrated semiconductor device 200 has two different gate oxide thicknesses, and each transistor 206 or 202 has a respective one selected from the two gate oxide thicknesses. Transistors of core circuit have a first gate oxide thickness, and transistors of input/output circuit have a second gate oxide thickness that is greater than the first gate oxide thickness. After the gate oxide layer 508 is formed, a layer of gate material (e.g. metal or polysilicon) 510 is deposited on the gate oxide layer 508, and is optionally patterned jointly with the gate oxide layer 508. The gate layer 510 is thereby patterned to a gate 202G of the PMOS transistor 202, a gate 206G of the NMOS transistor 206, and a plurality of separation gates 512 formed on top of the separation 226. In some implementations, a subset of the threshold adjustment ion implants in FIG. 5B is applied after the gate oxide layer 508 and gate layer 510 are deposited or patterned, i.e., the subset of the threshold adjustment ion implants penetrate the gate oxide layer and gate layer 510 to reach one or more of: the P-type channel 202C, the N-type channel 206C, the first portion 222A of the N-type semiconductor 222, and the first portion 242A of the P-type semiconductor 242.

Referring to FIG. 5D, a first lightly doped source and drain implant (P-type) is applied to form lightly doped regions of the source structure 202S and extended drain structure 202D of the PMOS transistor 202. A lightly doped region of the second portion 242B of the P-type semiconductor 242 of the P-type SBD 208 is formed via the same first lightly doped source and drain implant, so is a lightly doped region of a well contact of the P-well 218. A second lightly doped source and drain implant (N-type) is applied to form lightly doped regions of the source structure 206S and extended drain structures 206D of the NMOS transistor 206. A lightly doped region of the second portion 222B of the N-type semiconductor 222 of the N-type SBD 204 is formed via the same second lightly doped source and drain implant, so is a lightly doped region of a well contact of the N-well 216.

Referring to FIG. 5E, a first heavily doped source and drain implant (P-type) is applied to form heavily doped regions of the source structure 202S and extended drain structures 202D of the PMOS transistor 202. A heavily doped region of the second portion 242B of the P-type semiconductor 242 of the P-type SBD 208 is formed via the same first heavily doped source and drain implant, so is a heavily doped region of a well contact of the P-well 218. A second heavily doped source and drain implant (N-type) is applied to form heavily doped regions of the source structure 206S and extended drain structures 206D of the NMOS transistor 206. A heavily doped region of the second portion 222B of the N-type semiconductor 222 of the N-type SBD 204 is formed via the same second heavily doped source and drain implant, so is a heavily doped region of a well contact of the N-well 216. Each of these heavily doped regions sits within, and is integrated with, a respective lightly doped region of the same device structure.

Referring to FIGS. 5A-5E, impurity doping techniques include ion implantation of ionized atoms into a target region and in-situ physical/chemical deposition of a thin material layer containing the impurity atoms. In some situations, ion implantation or in-situ deposition is followed with annealing, i.e., a controlled heating cycle at a raised temperature to drive the impurity atoms into a certain depth of the target and activate localized crystal structures. By these means, specific electronic properties of semiconductor devices are enabled individually and in dedicated groups, such that the overall IC can be tested and qualified as a reliable product of performance over a range of operating conditions and application environments.

Referring to FIG. 5F, a silicon nitride (Si₃N₄) hard mask (RPO/SASB) is used to block silicidation. Portions of surfaces of the gate, source and drain structures of the transistors 202 and 206 are exposed via the Si₃N₄ hard mask, so are portions of surfaces of the first and second portions of the SBDs 204 and 208. A barrier metal (e.g., Pt, Ti or Co) is deposited on the Si₃N₄ hard mask and treated by heat to induce silicidation, while low-ohmic contacts are formed onto the exposed portions of surfaces of the gate, source and drain structures of the transistors 206 and 202 and the first and second portions of the SBDs 204 and 208. In some implementations, additional resistor areas are exposed via the Si₃N₄ hard mask, and salicidation occurs to the resistor areas to form resistors.

In some implementations, a silicide defining mask has a predefined critical dimension CD. In accordance with the silicide defining mask, a first silicide contact surface 514 is defined on the first portion 242A of the P-type semiconductor 242 of the P-type SBD 208, and a second silicide contact surface 516 is defined on the second portion 242B of the P-type semiconductor 242. The first silicide contact surface 514 is separated from the second portion 242B of the P-type semiconductor 242 of the P-type SBD 208 by a lateral distance l₁. The first silicide contact surface 514 is separated from the second silicide contact surface 516 by a lateral distance l₂. The lateral distances l₁ and l₂ are greater than the predefined critical dimension CD. In some implementations, in accordance with the silicide defining mask, a first silicide contact surface 518 is defined on the first portion 222A of the N-type semiconductor 222 of the N-type SBD 204, and a second silicide contact surface 520 is defined on the second portion 222B of the N-type semiconductor 222 of the N-type SBD 204. The first silicide contact surface 518 is separated from the second portion 222B of the N-type semiconductor 222 of the N-type SBD 204 by a lateral distance l₃. The first silicide contact surface 518 is separated from the second silicide contact surface 520 by a lateral distance l₄. The lateral distances l₃ and l₄ are greater than the predefined critical dimension CD. Further, in some implementations not shown, in accordance with the silicide defining mask, a silicide resistor is defined on the substrate 212. The silicide resistor is distinct from the extended drain structure 202D of the PMOS transistor 202 and the first portion 242A and the second portion 242B of the P-type semiconductor 242 of the P-type SBD 208. The lateral distances l₁-l₄are controlled by the predefined critical dimension CD, and the silicide defining mask is a critical mask for the planar SCMOS fabrication process 500.

After the FEOL of the planar Schottky CMOS fabrication process 500, a low-dielectric SiO₂-based dielectric layer is deposited and planarized, e.g., by chemical-mechanical polishing (CMP). Contacts are opened on the dielectric layer, and a metallic layer of interconnects are formed to access the gate, source and drain structures of the transistors 202 and 206 and the second portions and barrier metals of the SBDs 204 and 208 via the opened contacts. The metallic layer of interconnects are optionally made of aluminum (Al) or copper (Cu). In some implementations, a dual damascene process is applied, e.g., at a 0.18 μm or 0.13 μm level.

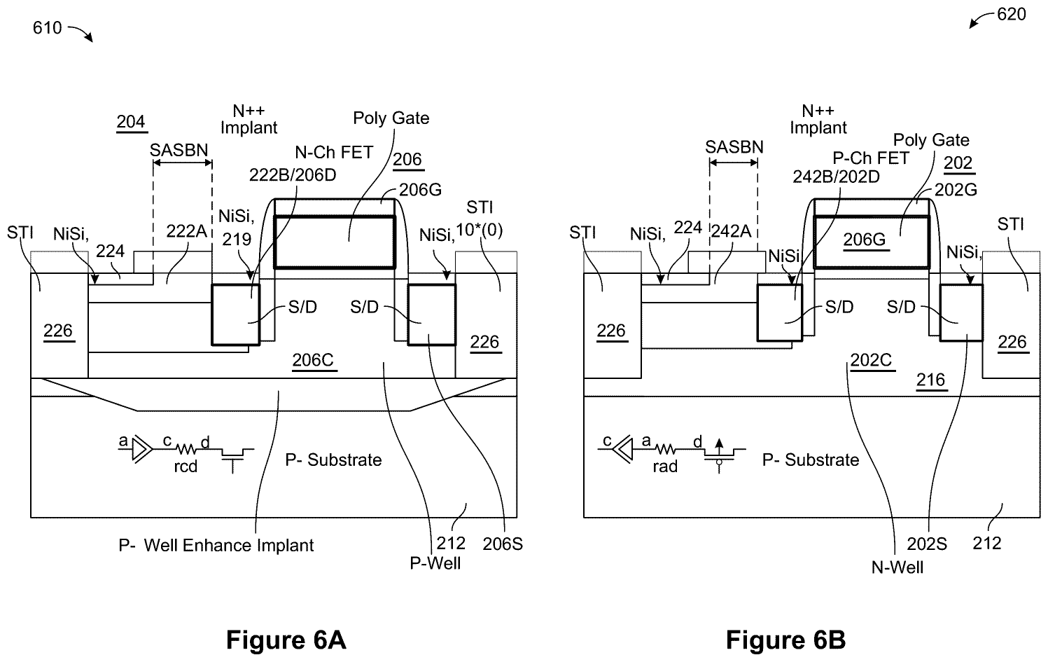

FIGS. 6A and 6B are two distinct cross-sectional views 610 and 620 of an integrated semiconductor device 200 that includes CMOS transistors and complementary SBDs and is processed up to completion of a FEOL, in accordance with some implementations. The cross-sectional views 610 and 620 correspond to different portions of a substrate 212. In an example, the substrate 212 includes a P-Type bulk silicon (e.g., having a resistivity of 10 ohm.cm). In another example, the substrate 212 includes an SOI, including an epitaxial silicon layer formed on a buried oxide. Referring to FIG. 6A, the integrated planar semiconductor device 200 at least includes an NMOS transistor 206 and an N-type SBD 204 formed on the substrate 212. The N-type SBD 204 is formed by joining an N-type semiconductor 222 and a barrier metal 224. A first doping concentration of the N-type channel 206C of the NMOS transistor 206 is substantially the same as that of a first portion 222A of the N-type semiconductor 222 of the N-type SBD 204. A doping profile of an extended drain structure 206D of the NMOS transistor is substantially the same as that of a second portion 222B of the N-type semiconductor 222. Referring to FIG. 5F, each of the extended drain structure 206D of the NMOS transistor 206 and the first portion 222A and the second portion 222B of the N-type semiconductor 222 has a distinct silicide contact surface 522, 518, or 520. In some implementations, the first portion 222A of the N-type semiconductor 222 has a first silicide contact surface 518, and the second portion 222B of the N-type semiconductor has a second silicide contact surface 520 that is separated from the first silicide contact surface 518 by a lateral distance l₄ (FIGS. 3F and 5F). The lateral distance l₄ is greater than a predefined critical dimension CD of a silicide defining mask.

In some implementations not shown, a silicide resistor is formed on the substrate 212. The silicide resistor is distinct from the extended drain structure 206D of the NMOS transistor 206 and the first portion 222A and the second portion 222B of the N-type semiconductor 222. A size of the silicide resistor is much greater than, and therefore, not limited by the critical dimension CD of the silicide defining mask. The source and drain structure 206S and 206D of the NMOS transistor 206 are formed via self-aligned salicidation without being limited by the critical dimension CD of the silicide defining mask. As a result, the predefined critical dimension CD of the silicide defining mask is controlled and defined based on the lateral distance l₃ or l₄ of the N-type SBD 204, which makes the non-critical silicide defining mask in a CMOS fabrication process become a critical mask in an SCMOS fabrication process integrating MOS transistors and SBDs.

In this example shown in FIG. 6A, both the N-type SBD 204 and the NMOS transistor 206 are formed in an P-well 218. Alternatively, in an example (e.g., in FIGS. 2A-2D), an N-type SBD 204 is located in a first P-well 218, and the NMOS transistor 206 is formed in a second P-well 236 distinct from the first P-well 218. Further, in some implementations, an P-type SBD 208 formed in an N-well 238 and by joining an P-type semiconductor 242 and a barrier metal 244. The N-well 238 is isolated from at least one of the first P-well 218 and the second P-well 236 by field oxide 226A.

In some implementations, the NMOS transistor 206 includes a first NMOS transistor. The integrated semiconductor device 200 further includes a second NMOS transistor configured to operate with a second N-type channel. The second N-type channel has an alternative doping concentration distinct from the first doping concentration, such that a first threshold voltage of the first NMOS transistor 206 is distinct from a second threshold voltage of the second NMOS transistor. By these means, multiple thresholds are available to form NMOS transistors, and multiple threshold doping concentrations can be selected to form the N-type semiconductor 222 of the N-type SBD 204.

In some implementations, the second portion 222B of the N-type semiconductor 222 includes a second region (e.g., a lightly doped region in FIG. 5D) where a third region (e.g., a heavily doped region in FIG. 5E) is formed and enclosed. In accordance with the doping profile, the second region has a second doping concentration, and the third region has a third doping concentration greater than the second doping concentration. The second doping concentration of the second portion 222B is greater than the first doping concentration of the first portion 222A.

In some implementations, a PMOS transistor 202 is formed in a first N-well 216 and configured to operate with an P-type channel 202C. Further, in some implementations, the N-type SBD 204 is located in the P-well (e.g., 218 in FIG. 2B) having an P-well access region 228. A doping concentration of the P-type channel of the PMOS transistor 202 is equal to that of a first portion 228A of the P-well access region 228, A doping profile of an extended drain structure of the PMOS transistor 202 matches that of a second P-type portion 228B of the P-well access region 228. The second P-type portion 228B of the P-well access region 228 is formed in the first portion 228A of the P-well access region 228 and has a distinct silicide contact surface. The first and second P-type portions 228A and 228B of the P-well access region 228 jointly provide a low-resistance path for the P-well 218.

In some implementations, the integrated semiconductor device 200 further includes an P-type SBD 208 formed in a second N-well. The P-type SBD 208 is formed by joining an P-type semiconductor 242 and a barrier metal 244. The first N-well and the second N-well are merged into a single N-well 216. Alternatively, in some implementations, the integrated semiconductor device 200 further includes an P-type SBD 208 formed in a second N-well. The first N-well is distinct from the second N-well.

In some implementations, the NMOS transistor 206 has a drain access 206DA coupled to the silicide contact surface 522 of the extended drain structure 206D of the NMOS transistor 206. The N-type SBD 204 has a cathode access 222C coupled to the silicide contact surface 520 of the second portion 222B of the N-type semiconductor 222. The drain access 206DA, the cathode access 222C, and the barrier metal 224 are formed from a first metallic layer.

In some implementations, the extended drain structure 206D of the NMOS device 206 overlaps the second portion 222B of the N-type semiconductor 222 of the N-type SBD 204. The NMOS 206 is directly coupled to the N-type SBD 204.

From a different perspective, referring to FIG. 6B, the integrated planar semiconductor device 200 includes a PMOS transistor 202 and a P-type SBD 208. The PMOS transistor 202 and P-type SBD 208 are formed on the substrate 212. The P-type SBD 208 joins a P-type semiconductor 242 and a barrier metal 244 (e.g., a metal cathode). A first doping concentration of the P-type channel 202C of the PMOS transistor 202 is substantially the same as that of a first portion 242A of the P-type semiconductor 242 of the P-type SBD 208. A doping profile of an extended drain structure 202D of the PMOS transistor 202 is substantially the same as that of a second portion 242B of the P-type semiconductor 242. Each of the extended drain structure 202D of the PMOS transistor 202C and the first portion 242A and the second portion 242B of the P-type semiconductor 242 has a distinct silicide contact surface 524, 514, or 516.

In some implementations, the first portion 242A of the P-type semiconductor 242 has a first silicide contact surface 514, and the second portion 242B of the P-type semiconductor 552 has a second silicide contact surface 516 that is separated from the first silicide contact surface 514 by a lateral distance l₂. The lateral distance l₂ is greater than a predefined critical dimension CD of a silicide defining mask.

In some implementations, the integrated semiconductor device 200 includes a silicide resistor that is formed on the substrate 212 and distinct from the extended drain structure 202D of the PMOS transistor 202 and the first portion 242A and the second portion 242B of the P-type semiconductor 242. A size of the silicide resistor is much greater than, and therefore, not limited by the critical dimension CD of the silicide defining mask. The source and drain structure 202S and 202D of the PMOS transistor 202 are formed via self-aligned salicidation without being limited by the critical dimension CD of the silicide defining mask. As a result, the predefined critical dimension CD of the silicide defining mask is controlled and defined based on the lateral distance l₁ or l₂ of the P-type SBD 208, which makes the non-critical silicide defining mask in the CMOS fabrication process become a critical mask in the SCMOS fabrication process integrating MOS transistors and SBDs.

In some implementations, the PMOS transistor 202 includes a first PMOS transistor. The integrated semiconductor device 200 includes a second PMOS transistor configured to operate with a second P-type channel. The second P-type channel has an alternative doping concentration distinct from the first doping concentration, such that a first threshold voltage of the first PMOS transistor 202 is distinct from a second threshold voltage of the second PMOS transistor.

In some implementations, the second portion 242B of the P-type semiconductor 242 includes a second region (e.g., a lightly-doped region) where a third region (e.g., a heavily-doped region) is formed and enclosed. In accordance with the doping profile, the second region has a second doping concentration, and the third region has a third doping concentration greater than the second doping concentration. The second doping concentration of the second region is greater than the first doping concentration of the first portion 242A.

In some implementations shown in FIGS. 4A-4D, both the P-type SBD 208 and the PMOS transistor 202 are formed in an N-well 216. Alternatively, in some implementations shown in FIGS. 2A-2D, the P-type SBD 208 is located in a first N-well 238, and the PMOS transistor 202 is formed in a second N-well 216 distinct from the first N-well 238. Further, in some implementations, the integrated semiconductor device 200 further includes an N-type SBD 204 formed in a P-well 218 and by joining an N-type semiconductor 222 and a barrier metal 224, wherein the P-well 218 is isolated from at least one of the first N-well 238 and the second N-well 216 by field oxide 226A.

In some implementations, an NMOS transistor 206 is formed in a first P-well 218 and configured to operate with an N-type channel 206C.

In some implementations, referring to FIGS. 2A-2D, the P-type SBD 208 is located in an N-well 238 having an N-well access region 248. A doping concentration of the N-type channel 202C of the NMOS transistor 202 is equal to that of a first N-type portion 248A of the N-well access region 248. A doping profile of an extended drain structure 202D of the NMOS transistor 202 matches that of a second portion 248B of the N-well access region 248. The second portion 248B of the N-well access region 248 is formed in the first N-type portion 248A of the N-well access region 248, and has a distinct silicide contact surface. The first and second N-type portions 248A and 248B of the N-well access region 248 jointly provide a low-resistance path for the N-well 238.

In some implementations, referring to FIGS. 4A-4D, an N-type SBD 204 is formed in a second P-well and by joining an N-type semiconductor 222 and a barrier metal 224. The first P-well 218 and the second P-well are merged into a single P-well 218. Alternatively, in some implementations, referring to FIGS. 2A-2D, an N-type SBD formed in a second P-well 236 and by joining an N-type semiconductor 222 and a barrier metal 244. The first P-well 218 is distinct from the second P-well 236.

In some implementations, the extended drain structure 202D of the PMOS device 202 overlaps the second portion 242B of the P-type semiconductor 242 of the P-type SBD 208. A drain of the PMOS 202 acts as an anode of the P-type SBD 208. The PMOS 202 corresponds one of the PMOS transistors 110 and 112B, and the P-type SBD 208 corresponds to one of the SBDS 102-106 in FIG. 1A.

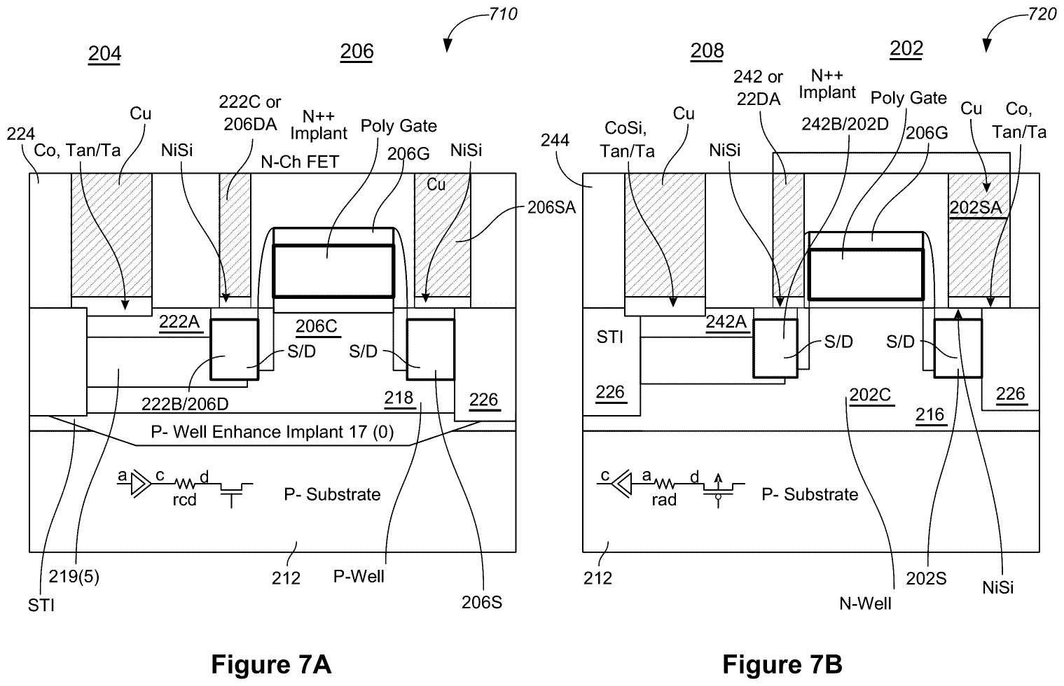

FIGS. 7A and 7B are two distinct cross-sectional views 710 and 720 of an integrated semiconductor device 200 that includes CMOS transistors 202 and 206 and complementary SBDs 204 and 208 and is processed to a first metallic layer in a back-end-of-line (BEOL), in accordance with some implementations. After the FEOL, surfaces of distinct silicide contact surfaces for a gate 202G, source structure 202S, and drain structure 202D of the PMOS transistor 202 are exposed, so are the surfaces of distinct silicide contact surfaces for a gate 206G, source structure 206S, and drain structure 206D of the NMOS transistor 206. Surfaces of the barrier metal 244 and the second portion 242B of the P-type semiconductor 242 of the P-type SBD 208 are exposed, so are the barrier metal 224 and the second portion 222B of the N-type semiconductor 222 of the N-type SBD 204. The first metallic layer is deposited and provide a plurality accesses to the exposed surfaces of distinct silicide contact surfaces. The first metallic layer is a combination of a barrier metal layer (e.g., Nickel, Nickel Silicide, Cobalt, Cobalt Silicide, and the like) and a conductive metal layer (e.g., copper). The barrier metal layer provides barrier metals 224 and 244 for the N-type SBD 204 and P-type SBD 208 and contact enhancing metal on each distinct silicide contact surface for the PMOS transistor 202, N-type SBD 204, NMOS transistor 206, and P-type SBD 208. The conductive metal layer is patterned to a first interconnect layer and provides accesses to an exposed portion of each distinct silicide contact surface for the PMOS transistor 202, N-type SBD 204, NMOS transistor 206, and P-type SBD 208.

In some implementations, referring to FIG. 7A, the NMOS transistor 206 has a drain access 206DA coupled to the silicide contact surface of the extended drain structure 206D of the NMOS transistor 206. The N-type SBD 208 has an anode access 242C coupled to the silicide contact surface of the second portion 242B of the P-type semiconductor 242. The drain access 206DA, cathode access 222C, and barrier metal 224 are formed from a first metallic layer. In some implementations, a source access 206SA is also formed from the first metallic layer. A subset of the source access 206SA, drain access 206DA, cathode access 222C and barrier metal 224 is electrically coupled via the first metallic layer. Further, in some implementations, the drain structure 206D of the NMOS transistor 206 and the second portion 222B of the N-type semiconductor 222 of the N-type SBD 204 optionally overlap with each other, so are the drain access 206DA and cathode access 222C. Conversely, in some implementations, the drain structure 206D and second portion 222B of the N-type semiconductor 222 overlap with each other and are buried under the first metallic layer without any drain or cathode access.

In some implementations, referring to FIG. 7B, the PMOS transistor 202 has a drain access 202DA coupled to the silicide contact surface of the extended drain structure 202D of the PMOS transistor 202. The P-type SBD 208 has an anode access 242C coupled to the silicide contact surface of the second portion 242B of the P-type semiconductor 242. The drain access 202DA, the anode access 242C, and the barrier metal 244 are formed from a first metallic layer. In some implementations, a source access 202SA is also formed from the first metallic layer. A subset of the source access 202SA, drain access 202DA, anode access 242C and barrier metal 244 is electrically coupled via the first metallic layer (e.g., via an interconnect 702). Further, in some implementations, the drain structure 202D of the PMOS transistor 202 and the second portion 242B of the P-type semiconductor 242 of the P-type SBD 208 optionally overlap with each other, so are the drain access 202DA and anode access 242C. Conversely, in some implementations, the drain structure 202D and second portion 242B of the P-type semiconductor 242 overlap with each other and are buried under the first metallic layer without any drain or anode access.

In some implementations not showed, each of silicide contact surfaces of a gate 206G of the NMOS transistor 206 and a gate 202G of the PMOS transistor 202 is at least partially covered by the first metallic layer and accessed by a respective gate access. The respective gate access is optionally coupled to a subset of gates, sources, and drains of CMOS transistors and/or a subset of barrier metals and semiconductors of complementary SBDs formed on the substrate 212 of the integrated semiconductor device 200, e.g., via the first metallic layer and/or any other interconnect layer formed above the first metallic layer.

It should be understood that the particular order in which the operations in each of the above figures have been described are merely exemplary and are not intended to indicate that the described order is the only order in which the operations could be performed. One of ordinary skill in the art would recognize various ways to form an integrated semiconductor device having a MOSFET device and an SBD device on the same substrate as described herein. Additionally, it should be noted that details described with respect to one of the above processes (e.g., in FIGS. 3A-3F or 5A-5F) are also applicable in an analogous manner to any other ones of the above processes. For brevity, the analogous details are not repeated.

It will also be understood that, although the terms first, second, etc. are, in some instances, used herein to describe various elements, these elements should not be limited by these terms. These terms are only used to distinguish one element from another. For example, a first type of audio feature can be termed a second type of audio feature, and, similarly, a second type of audio feature can be termed a first type of audio feature, without departing from the scope of the various described implementations. The first type of audio feature and the second type of audio feature are both types of audio features, but they are not the same type of audio feature.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

The foregoing description, for purpose of explanation, has been described with reference to specific implementations. However, the illustrative discussions above are not intended to be exhaustive or to limit the scope of the claims to the precise forms disclosed. Many modifications and variations are possible in view of the above teachings. The implementations were chosen in order to best explain the principles underlying the claims and their practical applications, to thereby enable others skilled in the art to best use the implementations with various modifications as are suited to the particular uses contemplated.

What is claimed is:

1. A method of forming an integrated and planar semiconductor device, comprising:
forming a P-type Metal Oxide Semiconductor (PMOS) transistor and a P-type Schottky barrier diode (SBD) on a substrate, wherein the P-type SBD is formed by joining a P-type semiconductor and a first barrier metal, including:
establishing a doping concentration of the P-type channel of the PMOS transistor and forming a first portion of the P-type semiconductor of the SBD concurrently;
forming an extended drain structure of the PMOS transistor and a second portion of the P-type semiconductor concurrently on the substrate concurrently; and
forming distinct silicide contact surfaces for the extended drain structure of the PMOS transistor and the first portion and the second portion of the P-type semiconductor of the P-type SBD concurrently.

2. The method of claim 1, further comprising, in accordance with a silicide defining mask having a predefined critical dimension:
defining a first silicide contact surface of the first portion of the P-type semiconductor;
defining a second silicide contact surface of the second portion of the P-type semiconductor, the second silicide contact surface being separated from the first silicide contact surface by a lateral distance, the lateral distance being greater than the predefined critical dimension.

3. The method of claim 2, further comprising, in accordance with the silicide defining mask, defining a silicide resistor on the substrate, wherein the silicide resistor is distinct from the extended drain structure of the PMOS transistor and the first portion and the second portion of the P-type semiconductor.

4. The method of claim 1, wherein the PMOS transistor includes a first PMOS transistor, the method further comprising:
forming a second PMOS transistor configured to operate with a second P-type channel, wherein the second P-type channel has an alternative doping concentration distinct from the doping concentration of the P-type channel of the first PMOS transistor, such that a first threshold voltage of the first PMOS transistor is distinct from a second threshold voltage of the second PMOS transistor, including:
establishing the alternative doping concentration of the second P-type channel of the second PMOS transistor, separately from the P-type channel of the first PMOS transistor and the first portion of the P-type semiconductor of the P-type SBD.

5. The method of claim 1, wherein each of the second portion of the P-type semiconductor and the extended drain structure of the PMOS transistor includes a respective second region where a respective third region is formed and enclosed, and forming the extended drain structure of the PMOS transistor and the second portion of the P-type semiconductor concurrently on the substrate further comprising, in accordance with the doping profile:
forming the second regions of the second portion of the P-type semiconductor and the extended drain structure having a second doping concentration, concurrently using a first drain doping operation;
forming the third region of the second portion of the P-type semiconductor in the second region of the second portion of the P-type semiconductor and the third region of the extended drain structure in the second region of the extended drain structure, concurrently using a second drain doping operation, the third regions having a third doping concentration;
wherein the third doping concentration is greater than the second doping concentration, and the second doping concentration is greater than the first doping concentration of the first portion.

6. The method of claim 1, further comprising, concurrently in accordance with a well defining mask:
forming a first N-well where the P-type SBD is located;
forming a second N-well where the PMOS transistor is located, the second N-well distinct from the first N-well.

7. An integrated planar semiconductor device, comprising:
a substrate;
a P-type Metal Oxide Semiconductor (PMOS) transistor formed on the substrate; and
a P-type SBD formed on the substrate and by joining a P-type semiconductor and a first barrier metal;
wherein a first doping concentration of the P-type channel of the PMOS transistor is substantially the same as that of a first portion of the P-type semiconductor of the P-type SBD;
wherein a doping profile of an extended drain structure of the PMOS transistor is substantially the same as that of a second portion of the P-type semiconductor; and
wherein each of the extended drain structure of the PMOS transistor and the first portion and the second portion of the P-type semiconductor has a distinct silicide contact surface.

8. The semiconductor device of claim 7, wherein the first portion of the P-type semiconductor has a first silicide contact surface, and the second portion of the P-type semiconductor has a second silicide contact surface that is separated from the first silicide contact surface by a lateral distance, the lateral distance being greater than a predefined critical dimension of a silicide defining mask.

9. The semiconductor device of claim 7, further comprising:
a silicide resistor that is formed on the substrate and distinct from the extended drain structure of the PMOS transistor and the first portion and the second portion of the P-type semiconductor.

10. The semiconductor device of claim 7, wherein the PMOS transistor includes a first PMOS transistor, the semiconductor device further comprising:
a second PMOS transistor configured to operate with a second P-type channel, wherein the second P-type channel has an alternative doping concentration distinct from the first doping concentration, such that a first threshold voltage of the first PMOS transistor is distinct from a second threshold voltage of the second PMOS transistor.

11. The semiconductor device of claim 7, wherein:
the second portion of the P-type semiconductor includes a second region where a third region is formed and enclosed;
in accordance with the doping profile, the second region has a second doping concentration, and the third region has a third doping concentration greater than the second doping concentration; and
the second doping concentration of the second region is greater than the first doping concentration of the first portion.

12. The semiconductor device of claim 7, wherein the P-type SBD is located in a first N-well, and the PMOS transistor is formed in a second N-well distinct from the first N-well.

13. The semiconductor device of claim 12, further comprising:
an N-type SBD formed in a P-well and by joining an N-type semiconductor and a second barrier metal, wherein the P-well is isolated from at least one of the first N-well and the second N-well by field oxide.

14. The semiconductor device of claim 7, wherein both the P-type SBD and the PMOS transistor are formed in an N-well.

15. The semiconductor device of claim 7, further comprising:
an N-type Metal Oxide Semiconductor (NMOS) transistor formed in a first P-well and configured to operate with an N-type channel.

16. The semiconductor device of claim 15, wherein
the P-type SBD is located in an N-well having an N-well access region;
a doping concentration of the N-type channel of the NMOS transistor is equal to that of a first portion of the N-well access region;
a doping profile of an extended drain structure of the NMOS transistor matches that of a second portion of the N-well access region, the second portion of the N-well access region formed in the first portion of the N-well access region and having a distinct silicide contact surface; and
the first and second portions of the N-well access region jointly provide a low-resistance path for the N-well.

17. The semiconductor device of claim 15, further comprising:
an N-type SBD formed in a second P-well and by joining an N-type semiconductor and a second barrier metal, wherein the first P-well and the second P-well are merged into a single P-well.

18. The semiconductor device of claim 15, further comprising:
an N-type SBD formed in a second P-well and by joining an N-type semiconductor and a second barrier metal, wherein the first P-well is distinct from the second P-well.

19. The semiconductor device of claim 7, wherein:
the PMOS transistor has a drain access coupled to the silicide contact surface of the extended drain structure of the PMOS transistor;
the P-type SBD has an anode access coupled to the silicide contact surface of the second portion of the P-type semiconductor, and
the drain access, the anode access, and the first barrier metal are formed from a first metallic layer.

20. The semiconductor device of claim 7, wherein the extended drain structure of the PMOS device overlaps the second portion of the P-type semiconductor of the P-type SBD.
